(19) United States
(12) Patent Application Publication
(10) Pub. No.: US 2014/0340975 A1
(43) Pub. Date: Nov. 20, 2014

(54) SEMICONDUCTOR INTEGRATED CIRCUIT AND METHOD OF TESTING SEMICONDUCTOR INTEGRATED CIRCUIT

(71) Applicant: FUJITSU LIMITED, Kawasaki-shi (JP)

(72) Inventor: Keigo NAKATANI, Kawasaki (JP)

(21) Appl. No.: 14/447,146

(22) Filed: Jul. 30, 2014

Related U.S. Application Data
(63) Continuation of application No. PCT/JP2012/052502, filed on Feb. 3, 2012.

(51) Int. Cl. G11C 29/04

(52) U.S. Cl. CPC G11C 29/04
USPC 365/201

(57) ABSTRACT

A semiconductor integrated circuit is provided with: a memory under test; a test-result-storage memory; a test-data generation part for generating in a sequential manner a test address signal and test data for supplying to the memory under test; and a control circuit. The control circuit includes a delay circuit, which, when the control circuit stores in a sequential manner in the test-result-storage memory a test result according to the test address signal and test data in the memory under test, delays the storage-destination address signal in the test-result-storage memory from the test address signal set in the memory under test, in accordance with a time delay that includes at the least the latency from the setting of the test address signal in the memory under test to the reading out of the test data.

### CROSS-REFERENCE TO RELATED APPLICATION

This application is a continuation application of International Application PCT/JP2012/052502 filed on Feb. 3, 2012 and designated the U.S., the entire contents of which are incorporated herein by reference.

### FIELD

The embodiments discussed herein are related to a semiconductor integrated circuit and a method of testing the semiconductor integrated circuit.

### BACKGROUND

With developments of semiconductor manufacturing technologies over the recent years, random access memories (RAMs) can be packaged on a variety of semiconductor chips exemplified by processor chips. In the case of packaging the RAM on the semiconductor chip, however, it is requested to effectively test the RAM.

FIG. 1 illustrates a method of testing the RAM. FIG. 1 illustrates a large-scale integrated circuit (LSI) tester to perform testing and a test target LSI. The test target LSI includes a random access memory-built-in self-test (RAM-BIST) circuit, a test target RAM and a data receiver. The RAM-BIST circuit will hereinafter be simply referred to as the RAM-BIST.

A configuration in FIG. 1 is that the RAM-BIST transmits items of data for testing such as an address of the RAM, write data, a R/W signal of switching over writing or reading and an Enable signal to the test target RAM. Further, the RAM-BIST transmits, e.g., an expected value, the Enable signal for the data receiver, etc. to the data receiver.

On the other hand, the data receiver includes the same number of comparators as a bit count (a number of bits) of the RAM, which compare the expected value with a value read from a specified address. Then, the data receiver stores a result of the comparison between the expected value and the read value as a test result in an unillustrated register. Note that a status of “the expected value being different from the read value” is called “Fail”.

When testing a plurality of addresses in the RAM and if Fail occurs at any one of bits of one address, the data receiver is structured to retain a Fail status. Namely, the registers of the data receiver are provided, for example, on a bit-by-bit basis of a word specified by one address. Then, the register associated with the bit becoming the Fail status is set to “1” or “High”, thereby retaining the Fail status. Therefore, for instance, when sequentially testing all the addresses in the RAM, the test results are stored in the respective bits (i.e., respective registers) of the data receiver. The test results to be stored are an accumulation of the test results of the whole addresses in the RAM.

When finishing the test, values of the data receiver are read from SOUT terminals by conducting a scan shift, i.e., a sequential shift, thereby making it possible to determine whether acceptable or not on the bit-by-bit basis of the RAM. Note that initialization of the values of the data receiver involves using the scan shift or a reset signal. Further, the LSI tester performs setting for the test within the LSI through the scan shift. The “setting for the test” is exemplified by setting an occurrence condition of the test data to the RAM-BIST, and so on.

In the configuration of FIG. 1, however, as described above, the test results to be stored in the respective registers of the data receiver are the accumulation of the test results of the whole addresses in the RAM. Therefore, in the configuration of FIG. 1, the address brought into the Fail status cannot be distinguished.

On the other hand, in the configuration of FIG. 1, if the test result is contrived to be read out from the test result by the scan shift after performing the test with respect to one address of the RAM, the address brought into the Fail status can be distinguished. However, it follows that the test result is scan-shifted whenever performing the test with respect to one address, and the test is hard to be done at a high speed.

FIG. 2 is a diagram depicting an improved plan of the testing method illustrated in FIG. 1. The improved plan of the method in FIG. 1 is that the test results are stored in the RAM dedicated for a Fail memory in place of the data receiver within the LSI in FIG. 2. FIG. 2 also illustrates the LSI and the LSI tester connected to the LSI. The LSI includes a control circuit, a BIST circuit, the RAM for processing, a checker and the RAM for the Fail memory. A basic operation in the configuration in FIG. 2 is, however, the same as the conventional operation. To be specific, an operation of the BIST circuit in FIG. 2 is the same as in the case of FIG. 1. Moreover, the checker and the RAM for the Fail memory correspond to the data receiver in FIG. 1.

In FIG. 1, however, the test results are stored in a latch group on a bit-by-bit basis of the data for one address within the data receiver. On the other hand, in FIG. 2, the test results defined as results of comparisons by the checker are stored in the dedicated RAM (the RAM for the Fail memory). The data receiver in FIG. 1 is, the test results being retained in the group of latches corresponding to the bits for one address, hard to analyze an error in distinction between the addresses. In FIG. 2, a problem in FIG. 1 is improved, and it is feasible to retain, per address, the test results in the test target RAM (the RAM for processing) at the high speed.

### DOCUMENT OF PRIOR ART

[Patent Document]
[Patent document 1] Japanese Patent Application Laid-Open Publication No. 2005-141797
[Patent document 2] Japanese Patent Application Laid-Open Publication No. H11-238400

### SUMMARY

One aspect of a technology of the disclosure can be exemplified by a semiconductor integrated circuit that follows. The semiconductor integrated circuit includes: a test target memory; a test result storage memory; a test data generating unit to sequentially generate a test address signal and test data to be supplied to the test target memory; and a control circuit including a delay circuit to delay, when sequentially storing in the test result storage memory test result data based on the test address signal and the test data supplied to the test target memory, a storage destination address signal to be supplied to the test result storage memory than the test address signal to be supplied to the test target memory, in accordance with a time delay containing at least a latency between supplying the test address signal to the test target memory and reading corresponding test result data.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a diagram illustrating a method of testing a RAM;

FIG. 2 is a diagram illustrating an improved plan of the testing method;

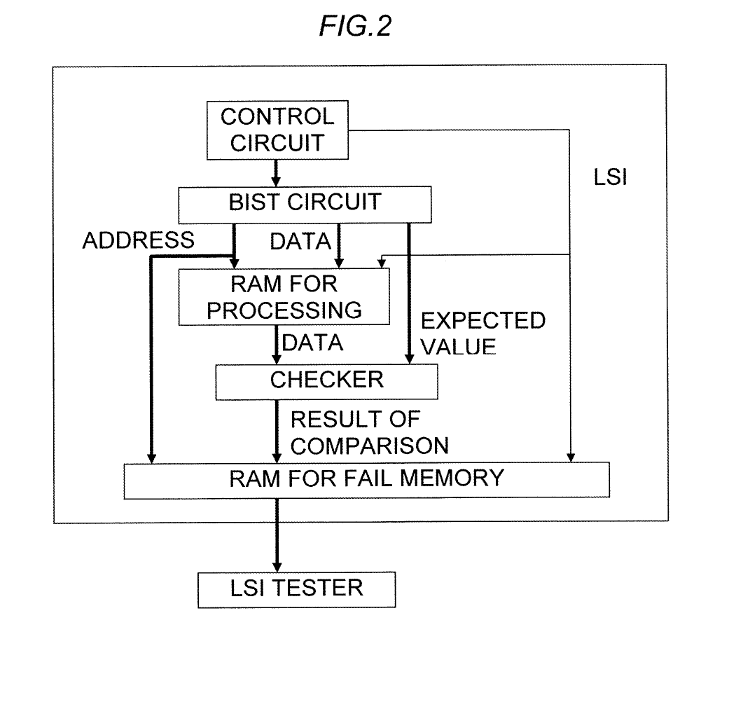

FIG. 3 is a diagram illustrating a configuration of a semiconductor integrated circuit according to an Example 1;

FIG. 4 is a diagram illustrating a time chart in a case where a RAM 1 is set as a test target, and a RAM 2 is set as a test result storage destination;

FIG. 5 is a diagram illustrating a configuration of an FBM control circuit;

FIG. 6 is a diagram illustrating a configuration of a data receiver;

FIG. 7 is a diagram illustrating a configuration of the semiconductor integrated circuit according to an Example 2;

FIG. 8 is a diagram illustrating a configuration of the FBM control circuit according to the Example 2;

FIG. 9 is a diagram illustrating a configuration of the semiconductor integrated circuit according to an Example 3;

FIG. 10 is a diagram illustrating a structure of data stored in a memory for storing test results;

FIG. 11 is a diagram illustrating a configuration of the FBM control circuit according to the Example 3.

### DETAILED DESCRIPTION

In an LSI including a dedicated RAM for storing test results, the test results of a target RAM of the LSI are retained in the dedicated RAM, whereby the test target RAM can be tested fast and the test results can be retained per address. However, technologies of the LSI give no consideration to an influence of the latency in the test target RAM. For example, the latency differs depending on characteristics, operating conditions, etc. of the test target RAM as the case may be. In the LSI, the process of analyzing the test results of the RAM to retain the test results is therefore complicated. The present semiconductor integrated circuit facilitates the analysis of the test result by excluding the influence of a latency in the test target memory.

A semiconductor integrated circuit according to an aspect of an embodiment will hereinafter be described with reference to the drawings. A configuration of the following embodiment is an exemplification, and the present semiconductor integrated circuit is not limited to the configuration of the embodiment.

### Example 1

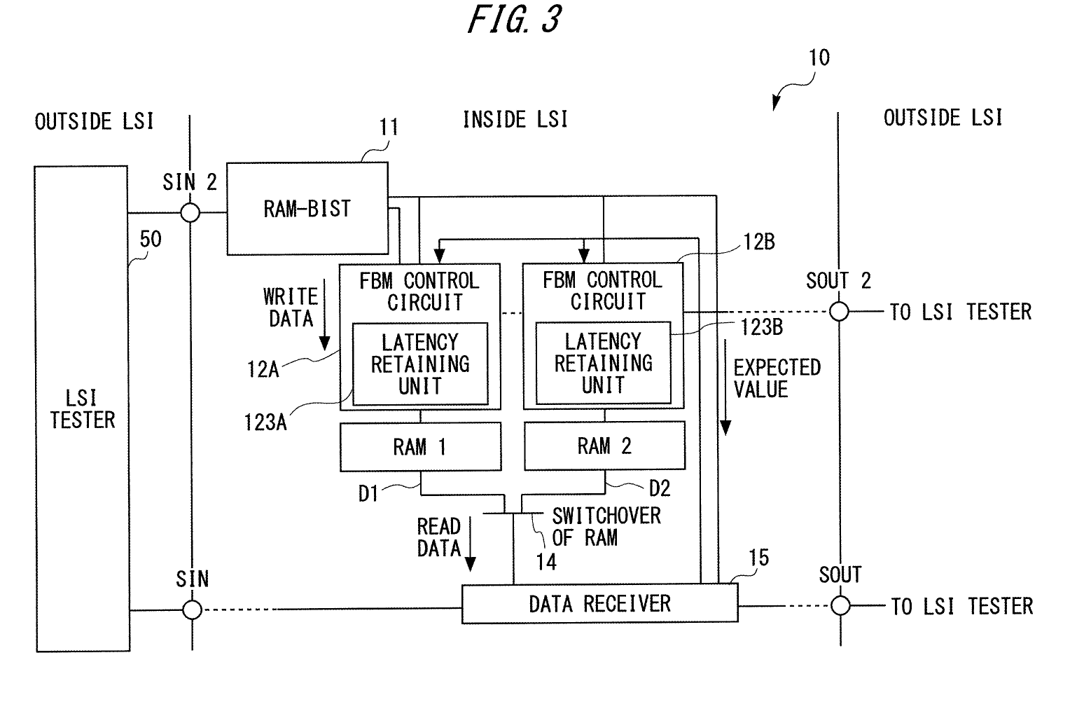

FIG. 3 illustrates a configuration of a semiconductor integrated circuit 10 according to a first working example (Example 1). Note that an LSI tester 50 is connected to the semiconductor integrated circuit 10. The LSI tester 50 sets test conditions with respect to the semiconductor integrated circuit 10.

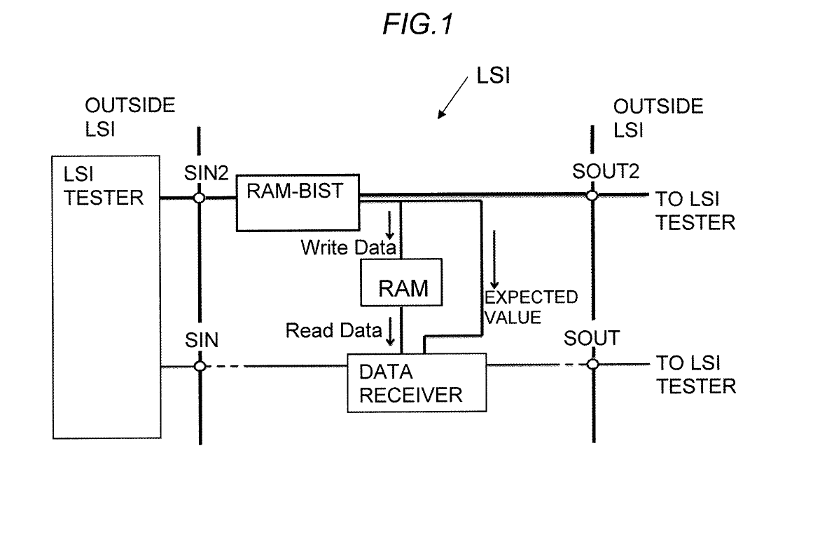

The semiconductor integrated circuit 10 includes a RAM-BIST 11, Fail Bit Memory (FBM) control circuits 12A, 12B, a RAM 1, a RAM 2, a selector 14 and a data receiver 15. In the configuration of FIG. 1, write data (Write Data) sent from the RAM-BIST 11 are transferred to the RAM 1 and the RAM 2 via the FBM control circuits 12A, 12B. The data receiver 15 is connected via the selector 14 to the RAM 1 and the RAM 2. Then, if the RAM 1 is set as a test target, a test result is stored in the RAM 2 through the data receiver 15. Further, if the RAM 2 is set as the test target, the test result is stored in the RAM 1. The RAM 1 and the RAM 2 are given by way of one example of a RAM that is used interchangeably as a test target memory and as a test result storage memory. Moreover, the RAM 1 and the RAM 2 are each given by way of one example of the test target memory and the test result storage memory.

In the configuration described above, for example, if the RAM 1 is the test target, a disparity occurs between a test target address in the RAM 1 and a result storage address in the RAM 2 due to a latency in the RAM 1 or the data receiver 15 as the case may be. It therefore happens that an analysis of the test result is time-consuming in processing the data. The same is applied to a case of the RAM 2 being the test target. Herein, the term “latency” represents a period of time ranging from when setting, e.g., a read address in the RAM 1 up to when reading the data specified by the read address in the RAM 1. The latency is normally defined by a value with a clock cycle being a unit.

In the Example 1, the FBM control circuits 12A, 12B are provided with latency retaining units 123A, 123B respectively in order to avoid mismatching between the test target address and the result storage address due to the latency. In the semiconductor integrated circuit 10, e.g., when the RAM 1 is set as the test target, the result storage address in the RAM 2 stored with the test result is shifted by a quantity of the latency retained in the latency retaining unit 123B from the test target address specified in the RAM 1. As a result, the disparity between the test target address in the RAM 1 and the result storage address in the RAM 2 is obviated.

The RAM-BIST 11 sends the data (Write-Data in FIG. 3) for the test target to the FBM control circuits 12A, 12B, and sends also an expected value to the data receiver 15. Herein, the “data for the test target” is data to realize a write function and a read function to and from, e.g., the RAM 1, the RAM 2, etc. The “data for the test target” can be exemplified by addresses of the RAM 1, the RAM 2, etc. becoming the test targets, the data written to these addresses, a R/W signal (a switchover to the write or the read) and an Enable signal (ON/OFF of a RAM operation). Further, the “expected value” connotes data to be compared with the read data for verifying the read data from the RAM 1, the RAM 2, etc. becoming the test targets. The RAM-BIST 11 is given by way of one example of a test data generating unit.

Moreover, the RAM-BIST 11 may control a connecting destination of the selector 14, i.e., which RAM, the RAM 1 or the RAM 2, is connected to the data receiver 15. The connecting destination of the selector 14 may, however, be controlled by the data receiver 15.

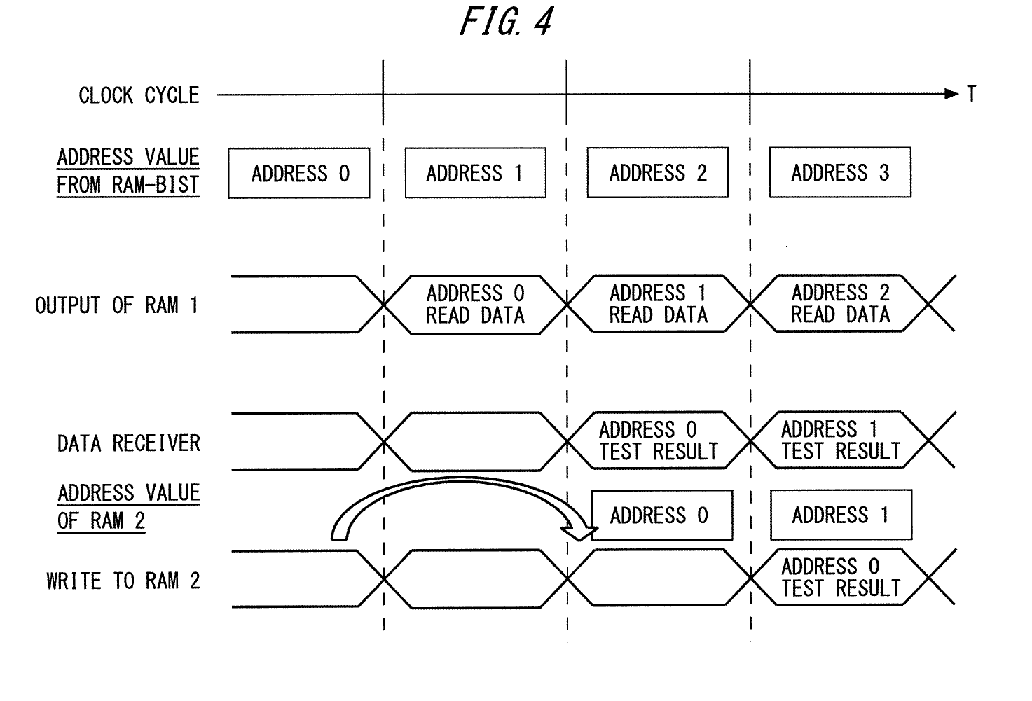

The FBM control circuits 12A, 12B control writing the data to the RAM 1 and the RAM 2, and set the read addresses of the data from the RAM 1 and the RAM 2. An in-depth description of configurations of the FBM control circuits 12A, 12B will be made based on FIG. 4. Note that the FBM control circuits 12A, 12B are, when generically termed, referred to simply as the FBM control circuit 12.

The RAM 1 and the RAM 2 receive, when the unillustrated R/W signal specifies the write (W), specified addresses and inputs of the write data from the FBM control circuits 12A, 12B, and store the write data to the specified addresses. Further, the RAM 1 and the RAM 2 receive, when the unillustrated R/W signal specifies the read (R), specified addresses from the FBM control circuits 12A, 12B, then read the data from the specified addresses, and output the data to the selector 14.

The selector 14 outputs, based on, e.g., a control signal given from the RAM-BIST 11, the data read from one of the RAM 1 and the RAM 2 to the data receiver 15. However, the selector 14 may switch over, based on the control signal given from the data receiver 15, the connecting destination of the data receiver 15 to between the RAM 1 and the RAM 2.

The data receiver 15 reads read data (Read Data) D1 from the specified address of the RAM 1 when testing the RAM 1. In this case, the FBM control circuit 12A on the side of the RAM 1 transmits the address, the write data and the R/W signal in an as-is state to the RAM 1. With this transmission, the data receiver 15 acquires the read data from the specified address set in the RAM 1. Then, the data receiver 15 compares the expected value acquired from the RAM-BIST 11 with the read data from the RAM 1, and stores a test result obtained as a result of the comparison in the RAM 2 via the FBM control circuit 12B on the side of the RAM 2. The test result is given by way of one example of test result data.

The FBM control circuit 12B on the side of the RAM 2 adjusts a storage destination address of the RAM 2 in a way that corresponds to a quantity of the latency given by latency of RAM+ latency of the data receiver. For example, an assumption is that the latency of RAM+the latency of the data receiver is totally 2 cycles given by “1+1” cycles. Then, the FBM control circuit 12B on the side of the RAM 2 inputs, to the RAM 2, an address transmitted from the RAM-BIST 11 before the 2 cycles, i.e., the total value of the latency. Namely, the FBM control circuit 12B on the side of the RAM 2 inputs, to the RAM 2, the address transmitted by the RAM-BIST 11 at a point of time shifted backward by the quantity of the latency from the present. Then, the FBM control circuit 12B writes the test result as the write data given from the data receiver 15 to the delayed address. Note that the R/W signal is hereat set in the RAM 2 so as to specify the write (Write Setting). The FBM control circuit 12B is given by way of one example of a control circuit.

The setting being thus done, it follows that the test result of each address in the RAM 1 is stored in the same address in the RAM 2 as the test target address of the RAM 1. Moreover, the FBM control circuit 12B has a latency retaining unit 123B, and assures that also in the case of testing a latency-variable RAM, the test result is stored in the same address in the RAM for storing the test result as the address in the test target RAM.

Note that setting of a test condition and setting of the latencies in the latency retaining units 123A, 123B as described above are conducted based on a scan shift by the LSI tester 50 from a SIN2 terminal.

FIG. 4 illustrates a time chart in a case where the RAM 1 is set as the test target, while the RAM 2 is set as the storage destination of the test result. FIG. 4 depicts the address value from the RAM-BIST 11, the output data of the RAM 1, the read data of the data receiver 15, the address set in the RAM 2 and the write data to the RAM 2 together with elapses of time, i.e., with clock cycles.

An example in FIG. 4 is that addresses 0-3 are output from the RAM-BIST 11 at clock cycles 0-3. Then, the RAM 1 outputs the data read from the address 0. From this output onward, the RAM 1 outputs the read data with a delay of 1 cycle for the setting of the address value from the RAM-BIST 11.

The data receiver 15 compares at the cycle 2 the read data from the address 0 of the RAM 1 with the expected value, and inputs the test result as a result of the comparison to the RAM 2. Accordingly, the test result for the address 0 of the RAM 1 is written to the RAM 2 at timing after 2 cycles counted since setting the address 0 in the RAM 1. Then, at the cycle 2, the FBM control circuit 12B sets, in the RAM 2, the address 0 given 2 cycles before from the RAM-BIST 11. As a result, the test result for the address 0 in the RAM 1 is stored at the address 0 of the RAM 2.

The procedure described so far is made on the assumption that the RAM 1 is set as the test target and the RAM 2 is set as the storage destination of the test result, however, the same procedure is applied to such a case that the RAM 2 is set as the test target and the RAM 1 is set as the storage destination of the test result. Further, in the example described above, the latency, i.e., the timing when the test result for the address 0 of the RAM 1 is written to the RAM 2, is set after 2 cycles counted since setting the address 0 in the RAM 1, however, it is feasible to process in the same way as in FIG. 4 also in the case of the latency being a value excluding “2” by retaining a proper latency in the latency retaining unit 123B and adjusting the write address to the RAM 2.

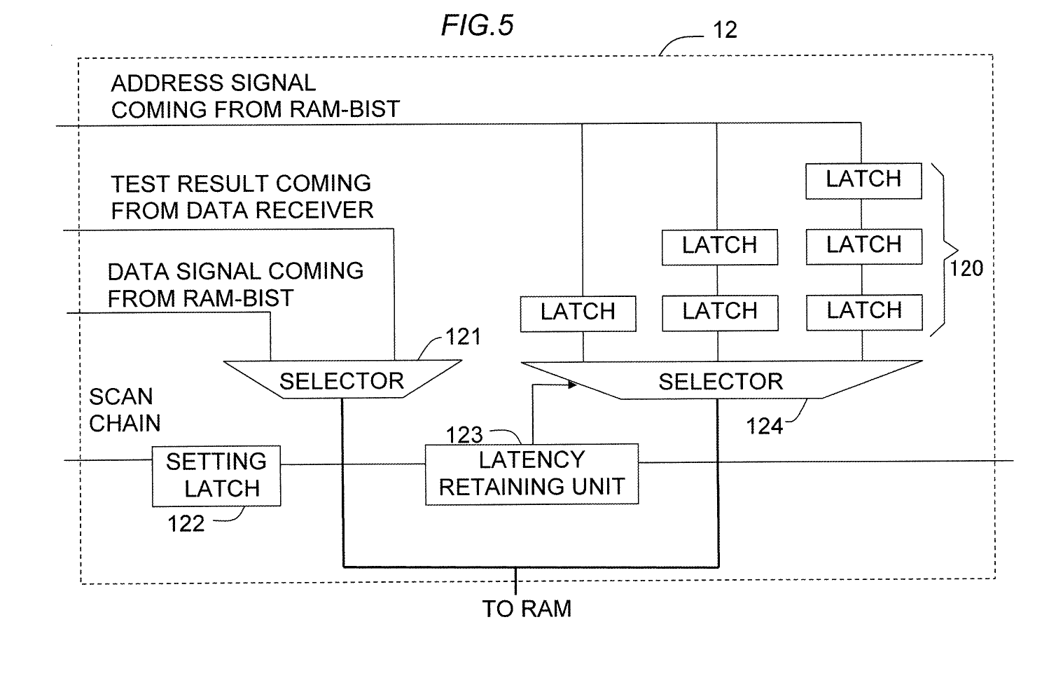

FIG. 5 illustrates a configuration of the FBM control circuit 12. The FBM control circuit 12 includes a selector 121 for data signals that are inputted to the RAM 1 and the RAM 2, a selector 124 for the address signal, a setting latch 122 to control the switchover of the signal at the selector 121, and a latency retaining unit 123 to control the switchover of the signal at the selector 124.

The selector 121 receives an input of the data of the test result from the data receiver 15 and an input of the signal of the write data from the RAM-BIST 11. The LSI tester 50 sets, in the setting latch 122 via a scan chain, an instruction value for selecting any one of the signal of the data of the test result from the data receiver 15 and the signal of the write data from the RAM-BIST 11, corresponding to which RAM, the RAM 1 or the RAM 2, becomes the test target.

For example, it is assumed that the RAM 1 is the test target, and the RAM 2 is the storage destination of the test result. In the FBM control circuit 12A on the side of the RAM 1, the setting latch 122 receives setting of the instruction value for selecting the signal of the write data from the RAM-BIST 11. The signal of the write data from the RAM-BIST 11 is therefore output to the RAM 1 via the FBM control circuit 12A. The selector 121 is one example of a write data selecting unit.

On the other hand, in the FBM control circuit 12B on the side of the RAM 2, the setting latch 122 receives the setting of the instruction value for selecting the signal of the data of the test result from the data receiver 15. Accordingly, the data of the test result from the data receiver 15 is output to the RAM 2 via the FBM control circuit 12B.

The selector 124 is provided with, e.g., four input signal terminals. It does not, however, mean that the number of the input signal terminals of the selector 124 is limited to “4”. A first input signal terminal receives an input of the address signal from the RAM-BIST 11 with no time delay. A second input signal terminal receives the input of the address signal from the RAM-BIST 11 via a single latch 120. It is herein assumed that a signal is output after 1 cycle counted since inputting the signal to the single latch 120. If via the latch 120 such as this, the second input signal terminal receives the input of the address signal transmitted from the RAM-BIST 11 one cycle earlier than the present point of time.

Similarly, a third input signal terminal receives the input of the address signal from the RAM-BIST 11 before 2 cycles via the two latches 120. Further, a fourth input signal terminal receives the input of the address signal from the RAM-BIST 11 before 3 cycles via the three latches 120. The selector 124 is therefore enabled to select any one of the address signals from the RAM-BIST 11 at the present point of time and the points of time till 3 cycles before counted from the present point of time, i.e., at four points of time. The latch 120 is one example of a delay circuit (a shift circuit).

As already described, the latency retaining unit 123 receives the setting of the instruction value corresponding to the latency till inputting the test result in the result storage destination, e.g., the RAM 2 since setting the address in the test target, e.g., the RAM 1. For instance, it is assumed that the RAM 1 is the test target and the RAM 2 is the storage destination of the test result. In the FBM control circuit 12A on the side of the RAM 1, the first input signal terminal with no time delay is selected in the latency retaining unit 123A. As a result, the address signal coming from the RAM-BIST 11 is set in the RAM 1 without making the time adjustment.

On the other hand, in the FBM control circuit 12B on the side of the RAM 2, the instruction value for selecting the signal input terminal corresponding to the latency is set in the latency retaining unit 123B. For example, as in FIG. 4, the latency till inputting the test result in the RAM 2 since setting the address in the RAM 1 is two cycles, in which case the latency retaining unit 123 (123B in FIG. 3) receives the setting of the instruction value for selecting the third input signal terminal including the two latches 120. Consequently, as illustrated in FIG. 4, the address signal coming from the RAM-BIST 11 before 2 cycles is set in the RAM 2. The latency retaining unit 123 and the selector 124 are given by way of one example of an address selecting unit.

The configuration described above enables the selector 121 to switch over the write data to the RAM 1 becoming the test target and the data of the test result for the RAM 2 for storing the test result. Moreover, the selector 124 can switch over the test target address for the RAM 1 becoming the test target and the address for the RAM 2 for storing the test result as well as adjusting the address corresponding to the latency.

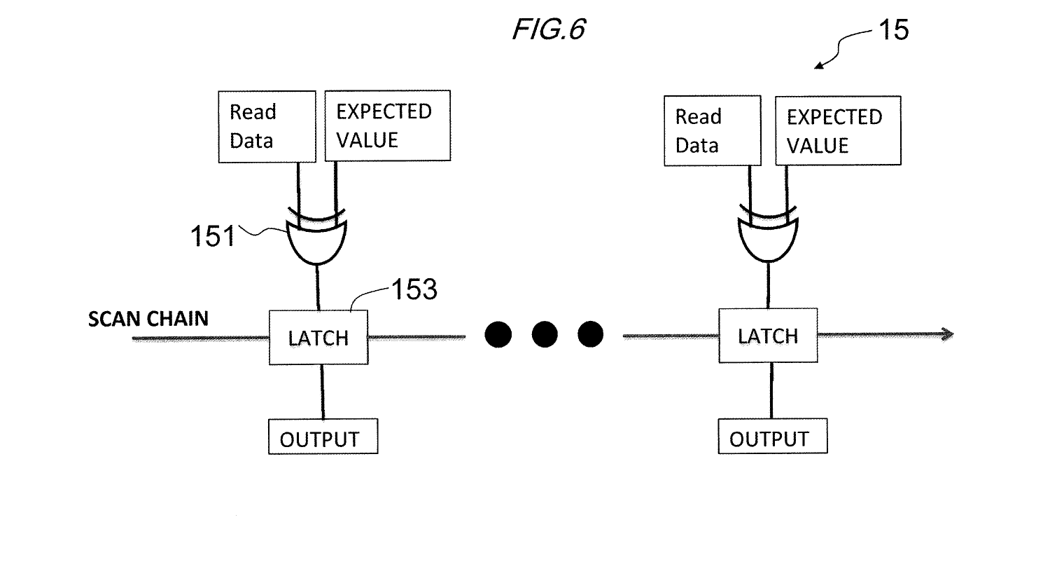

FIG. 6 is a diagram illustrating a configuration of the data receiver 15. The data receiver 15 includes an exclusive (EXOR) gate 151 to compare the read data (Read Data) from the test target with the expected value, and a latch 153. The EXOR gate 151 and the latch 153 are coupled as a tuple of components, and these tuples are prepared just as much as a bit count of a word of the test target to be tested at 1 cycle.

The EXOR gate 151, if the read data (Read Data) from the test target is coincident with the expected value, outputs “true” (a value “0”, a low potential signal L). Whereas if the read data (Read Data) from the test target is not coincident with the expected value, the EXOR gate 151 outputs “false” (a value “1”, a high potential signal H).

The latch 153 outputs the test result given by the EXOR gate 151 with a delay of 1 cycle. An output signal from the latch 153 is, as in FIG. 3, inputted to the RAM 2 from, e.g., the FBM control circuit 12B. Note that an initial value of the latch 153 is set through the scan chain. In the configuration of FIG. 6, however, a result of the determination of the EXOR gate 151 is set in the latch 153 and inputted to the RAM 2. Therefore, the setting of the initial value in the latch 153 may be omitted.

The configuration described above enables the data receiver 15 to test in parallel the respective bits of the read data of the test target tested at 1 cycle and to input the test result to the RAM 2 via the FBM control circuit 12. The data receiver 15 is one example of a test result generating unit.

As described above, the semiconductor integrated circuit 10 in the Example 1 has the configuration of providing the latency retaining units 123A, 123B respectively in the FBM control units 12A, 12B, and selecting the address signal transmitted from the RAM-BIST 11 earlier just as much as the latency than the present point of time in accordance with the latency till storing the test result since setting the address in the test target RAM. Then, the data receiver 15 compares the read data from the test target with the expected value from the RAM-BIST 11, and outputs the result of the comparison to the RAM for storing the result. Therefore, the test result can be stored in the RAM for storing the result in a way that specifies the same address as the test target address in the test target RAM. As a result, also in the case of analyzing the test result within the RAM for storing the result, a necessity for a laborious operation such as shifting the address etc. is eliminated, thereby enabling an efficient analysis to be performed.

Further, e.g., in such a case also that the latency varies corresponding to a type of the RAM, the setting in the RAM, etc., the instruction values corresponding to the respective latencies may be set in the latency retaining units 123A, 123B, and the address signal coming from the RAM-BIST 11 may be selected based on the latency.

### Example 2

The Example 1 has exemplified the configuration that in the semiconductor integrated circuit 10 including the two RAMs, i.e., the RAM 1 and the RAM 2, the same address as the test target address in the test target RAM is specified, and the test result can be stored in the RAM for storing the result. A second working example (Example 2) will exemplify a configuration that in a semiconductor integrated circuit 10C including a single RAM, the same processing as in the Example 1 is executed by switching over a bank within the RAM. Note that in the following Example 2, the same components as those in the Example 1 are marked with the same numerals and symbols, and their explanations are omitted.

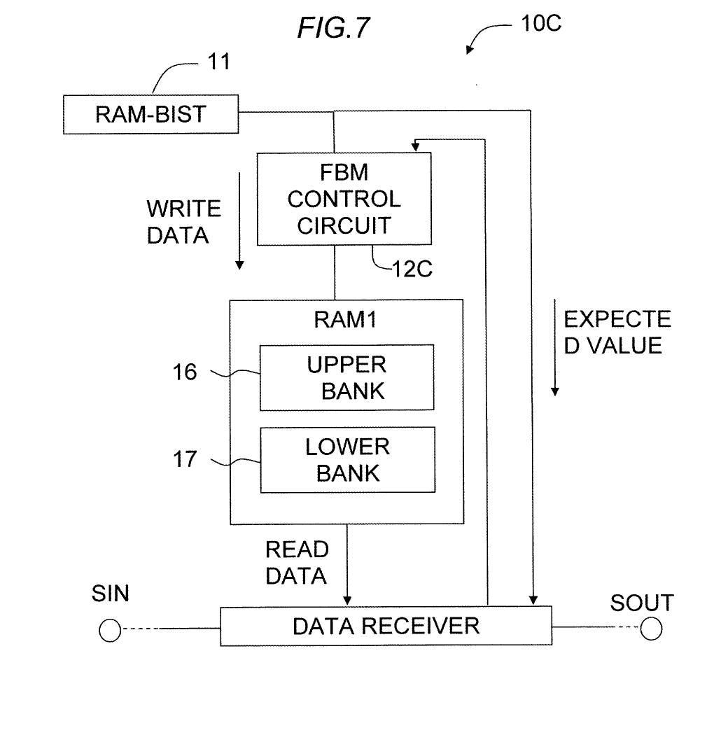

FIG. 7 illustrates a configuration of the semiconductor integrated circuit 10C according to the Example 2. The semiconductor integrated circuit 10C includes the RAM 1, and the RAM 1 has two banks, i.e., an upper bank 16 and a lower bank 17. For example, the upper bank 16 is an area in which a most significant bit (MSB) of the address is specified by “1”, while the lower bank 17 is an area in which the MSB of the address is specified by “0”. The RAM 1 may, however, be configured to include a plurality, equal to or larger than 3, of banks, e.g., banks 1-N. For instance, the RAM 1 may be configured to have four banks in which most significant 2 bits of the address are segmented by “00”, “01”, “10”, “11”, etc.

The RAM-BIST 11 outputs the write data and the address to the RAM 1 via an FBM control circuit 12C. Further, the RAM-BIST 11 sets the expected value in the data receiver 15. The data receiver 15 compares, in the same way as in the Example 1, the read data from the RAM 1 with the expected value, and writes the test result obtained as a result of the comparison to the RAM 1 via the FBM control circuit 12C. In the Example 2, however, any one of the upper bank 16 and the lower bank 17 becomes the test target, while the other bank becomes the storage destination of the test result. Such a configuration being attained, the semiconductor integrated circuit 10C in the Example 2 is configured to include the single RAM 1, in which the test result is, similarly to the Example 1, stored in the same address of the lower bank 17 as the test target address of the test target, e.g., the upper bank 16. Note that if the lower bank 17 is the test target, in the semiconductor integrated circuit 10C, the test result is stored in the same address in the upper bank 16 as the test target address.

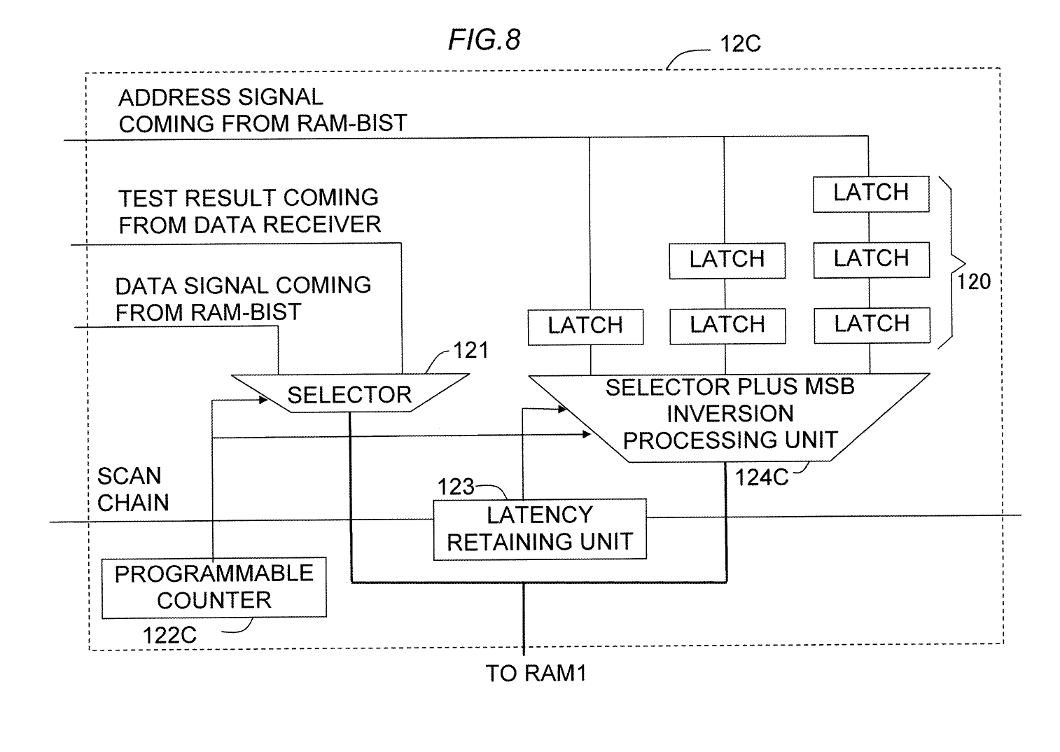

FIG. 8 depicts a configuration of the FBM control circuit 12C according to the Example 2. The FBM control circuit 12C in the Example 2 includes, as compared with the FBM control circuit 12 in the Example 1 (FIG. 5), a programmable counter 122C in place of the setting latch 122 (FIG. 5). Furthermore, the FBM control circuit 12C includes a selector plus (+) MSB bit inversion processing unit 124C as a substitute for the selector 124 (FIG. 5).

The programmable counter 122C receives, from the latency retaining unit 123, an input of the latency, i.e., a period of time (a cycle count of clock) till the data receiver 15 outputs the test result since a point of time when the address is set in the RAM 1, and counts a number corresponding to the latency. For example, when the latency is “1”, the programmable counter 122C inverts “0” or “1” in accordance with the clock. Further, when the latency is “2”, the programmable counter 122C performs counting in accordance with the clock such as 0→1→2→0 . . . . . . . Still further, when the latency is “N”, the programmable counter 122C performs counting in accordance with the clock such as 0→1→ . . . →N→0 . . . . Then, the programmable counter 122C, upon reaching a set value (latency), resets the count value at the next clock. Such a set value can be also called a frequency dividing value.

The selector 121 selects the write data from the RAM-BIST 11 when the count value of the programmable counter 122C is smaller than the set value (latency). While on the other hand, the selector 121 selects the write data from the data receiver 15 when the count value of the programmable counter 122C reaches the set value (latency).

Moreover, the selector plus MSB inversion processing unit 124C selects the data from the input signal terminal with no time delay when the count value of the programmable counter 122C is smaller than the set value (latency). While on the other hand, the selector plus MSB inversion processing unit 124C selects the input signal terminal associated with a latency value specified in the latency retaining unit 123 when the count value of the programmable counter 122C reaches the set value (latency). Moreover, the selector plus MSB inversion processing unit 124C inverts the MSB of the address given from the RAM-BIST 11 when the count value of the programmable counter 122C reaches the set value (latency).

With this configuration, the frequency dividing value, associated with the latency, in the latency retaining unit 123 is set in the programmable counter 122C, thus starting the test. The data signal from the RAM-BIST 11 is inputted to the RAM 1 via the selector 121. Further, the address given from the RAM-BIST 11 is output directly to the RAM 1 without via the latch 120 by making neither the time adjustment nor the inversion of the MSB.

Then, when the clock cycle advances ahead by the frequency dividing value, the count value of the programmable counter 122C reaches the set value (latency). Hereupon, the selector 121 selects the signal from the data receiver 15 and outputs the signal to the RAM 1. Further, the selector plus MSB inversion processing unit 124C selects the input signal terminal associated with the latency value specified in the latency retaining unit 123, and inverts the MSB of an address thereof. Hereupon, the selector plus MSB inversion processing unit 124C selects the address transmitted from the RAM-BIST 11 before a cycle count specified in the latency retaining unit 123, then inverts the MSB of this selected address, and outputs the inverted bit to the RAM 1.

(Processing Example)

Now, an assumption is that the upper bank 16 of the RAM 1 is the test target and the lower bank 17 is the storage destination of the test result. Another assumption is that the latency retaining unit 123 retains the “latency=2” similarly to the Example 1.

In this case, when the count value of the programmable counter 122C is smaller than the set value (latency=2), the RAM-BIST 11 outputs the write data for the upper bank 16 of the RAM 1 to the selector 121, and outputs also an address for the upper bank 16 to the selector plus MSB inversion processing unit 124C. Hereupon, the selector 121 outputs the write data given from the RAM-BIST 11 to the RAM 1. Further, the selector plus MSB inversion processing unit 124C outputs the address given from the RAM-BIST 11 directly to the RAM 1 without making the time adjustment. As a result, the write data is inputted to the address of the upper bank 16 of the RAM 1.

The write data to the address of the upper bank 16 of the RAM 1 is read after, e.g., 1 cycle. Then, the data receiver 15 outputs, to the FBM control circuit 12C in the same way as in the Example 1, a result of the comparison between the read data from the upper bank 16 of the RAM 1 and the expected value after another 1 cycle, i.e., 2 cycles counted since setting the address in the RAM 1.

By the way, after 2 cycles counted since setting the address in the RAM 1, the count value of the programmable counter 122C reaches the set value (latency=2). As a consequence, the selector 121 selects the test result from the data receiver 15. Moreover, the selector plus MSB inversion processing unit 124C acquires the address transmitted out of the RAM-BIST 11 before 2 cycles from the input signal terminal specified in the latency retaining unit 123, i.e., the input signal terminal having two latches 120, then inverts the MSB and inputs the inverted bit to the RAM 1.

The address MSB being inverted, an address existing before 2 cycles counted from the address of the test target upper bank 16 is set in the lower bank 17 of the RAM 1, and the test result is stored in this lower bank 17. To be specific, the test result of the upper bank 16 is stored in the address of the lower bank 17, this address being given by inverting the MSB of the address set as the test target address so far in the upper bank 16. In other words, the test result is stored in the same address in the lower bank 17 as the test target address in the upper bank 16. The upper bank 16 is one example of a test target area, and the lower bank 17 is one example of a test result storage area.

It is noted, it may be sufficient that when the lower bank 17 is set as the test target, the RAM-BIST 11 specifies the address of the lower bank 17 in the selector plus MSB inversion processing unit 124C and inputs the write data to the selector 121. Further, it is feasible to perform processing in the same way as described above also in the case of the latency being a value excluding “2” by setting a value corresponding to the latency in the count value of the programmable counter 122C according to the latency retaining unit 123.

As discussed above, even when the semiconductor integrated circuit 10C in the Example 2 is configured to include the single RAM, the RAM is divided into the banks, whereby the test result can be stored in the address of the result storage bank, this address being associated with the test target address of the test target bank. Herein, “the address being associated with the test target address” represents the address of which the MSB is inverted for the test target address but other bits are coincident.

### Example 3

A third working example (Example 3) will discuss a configuration that in a semiconductor integrated circuit 10D including a plurality of RAMs, one RAM is set as a RAM for storing the test result, while the remaining RAMs are set as the test target RAMs. Namely, the setting in the Example 1 is that one of the RAM 1 and the RAM 2 is the test target, while the other is the RAM for storing the test result. Further, in the Example 2, one of the upper bank 16 and the lower bank 17 is set as the test target, and the other is set as the bank for storing the test result. Accordingly, in the Examples 1 and 2, the test target area has the same storage capacity as the area for storing the test result has. The example 3 discusses a configuration in such a case that the storage capacity of the test target area is larger than the storage capacity of the area for storing the rest result. Moreover, in the Example 3, the plurality of RAMs is tested in parallel. Note that the same components in the Example 3 as those in the Examples 1 and 2 are marked with the same numerals and symbols, and the explanations thereof are omitted.

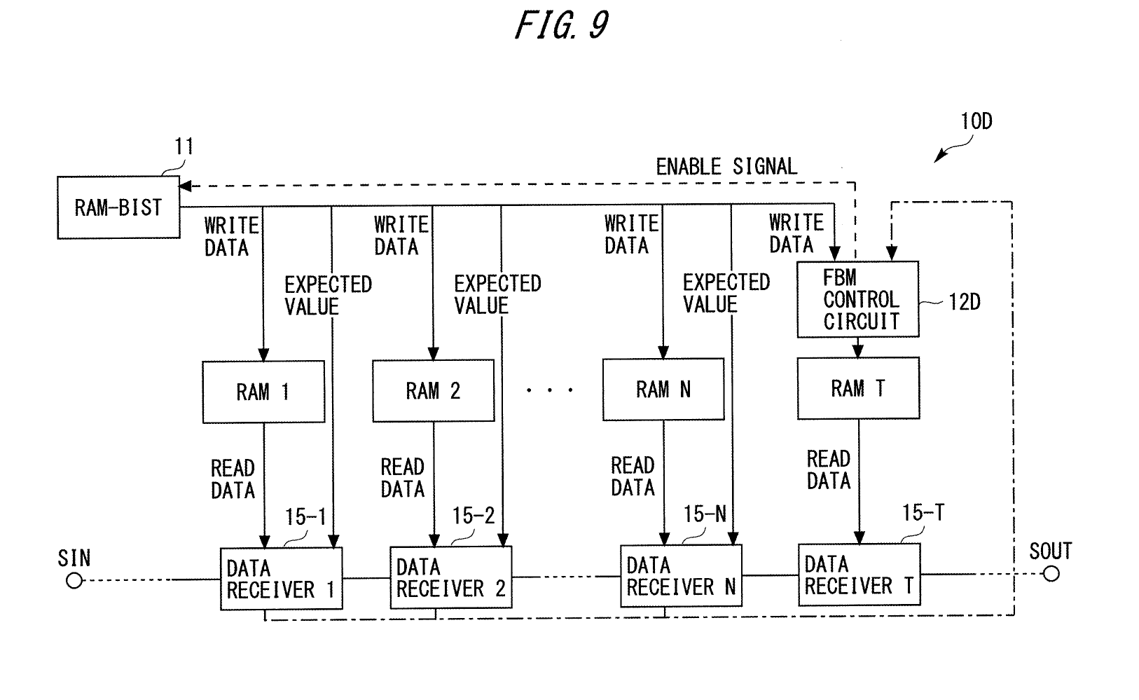

FIG. 9 illustrates a configuration of the semiconductor integrated circuit 10D according to the Example 3. The semiconductor integrated circuit 10D includes N-number of RAM 1 through RAM N and a RAM T for storing the test result. Data receivers 15-1 through 15-N and a data receiver 15-T are provided corresponding to the RAM 1 through RAM N and the RAM T. Furthermore, the semiconductor integrated circuit 10D includes the RAM-BIST 11 that transmits the write data to the N-number of RAM 1 through RAM N and transmits the expected value to the data receivers 15-1 through 15-N.

The RAM-BIST 11 is the same as that in the Examples 1 and 2 except a point that the RAM-BIST 11 is connected to the plurality of RAM 1 through RAM N and to the plurality of data receivers 15-1 through 15-N. In the Example 3, the RAM-BIST 11 transmits the data to the plurality of RAM 1 through RAM N and to the plurality of data receivers 15-1 through 15-N in parallel.

The data receivers 15-1 through 15-N compare, in the same manner as by the data receiver 15 in the Example 1, the read data from the RAM 1 through RAM N with the expected value given from the RAM-BIST 11, thereby obtaining the test result. In the Example 3, however, the test results for 1 word corresponding to test addresses in the data receivers 15-1 through 15-N are subjected to a logical OR operation and aggregated into 1-bit signals within the data receivers 15-1 through 15-N. A test result of the 1-bit signal aggregated from the test result for 1 word of the test target address, is called error existence/non-existence information. Pieces of error existence/non-existence information are transmitted in parallel respectively from the data receivers 15-1 through 15-N to the FBM control circuit 12D.

The FBM control circuit 12D, when receiving the 1-bit aggregated test results from the data receivers 15-1 through 15-N, determines whether an error exists or not, and further acquires the test result(s) for 1 word before being aggregated from the data receiver(s) (any one or more of the data receivers 15-1 through 15-N) from which the error is detected. Furthermore, the FBM control circuit 12D acquires a RAM number of the RAM 1 through RAM N with the occurrence of the error out of the data receiver from which the error detected. Then, the FBM control circuit 12D attaches the RAM number and the test address to the acquired test result for 1 word, and stores the test result attached with these items of data in the RAM T. Moreover, in the semiconductor integrated circuit 10D, the data given from the RAM-BIST 11 is not updated when stored in the RAM T, and the tests of the RAM 1 through RAM N are stopped.

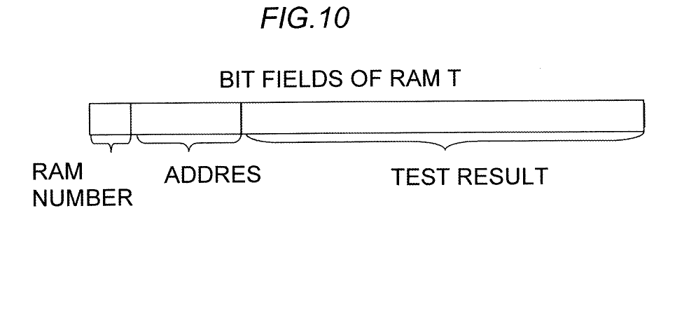

FIG. 10 illustrates a structure of the data to be stored in the memory (RAM T) for storing the test result. The data stored in the RAM T contains a RAM number of the RAM from which the error is detected, an address with the error being detected and data of the error-detected test result. Herein, the address is defined as a test address in any one of the test target RAM 1 through RAM N.

In the semiconductor integrated circuit 10D, a real address written to the RAM T is incremented each time the error is detected. Upon detecting the error, the FBM control circuit 12D writes the relevant RAM number, address and test result to the RAM T as illustrated in FIG. 10. It may be sufficient that the FBM control circuit 12D shifts back the test address for the storage in the RAM T just as much as a quantity given by adding the latency of the RAM to the latency of the data receiver as in the case of the Examples 1 and 2. To be more specific, the FBM control circuit 12D organizes the test data by combining the address transmitted from the RAM-BIST 11 before a latency cycle count from the present point of time, the RAM number and the test result together, and writes the test data to the RAM T. It may be sufficient that the unillustrated LSI tester reads the test data stored in the RAM T into the data receiver 15-T and further reads the test data up to an SOUT terminal by scan shift.

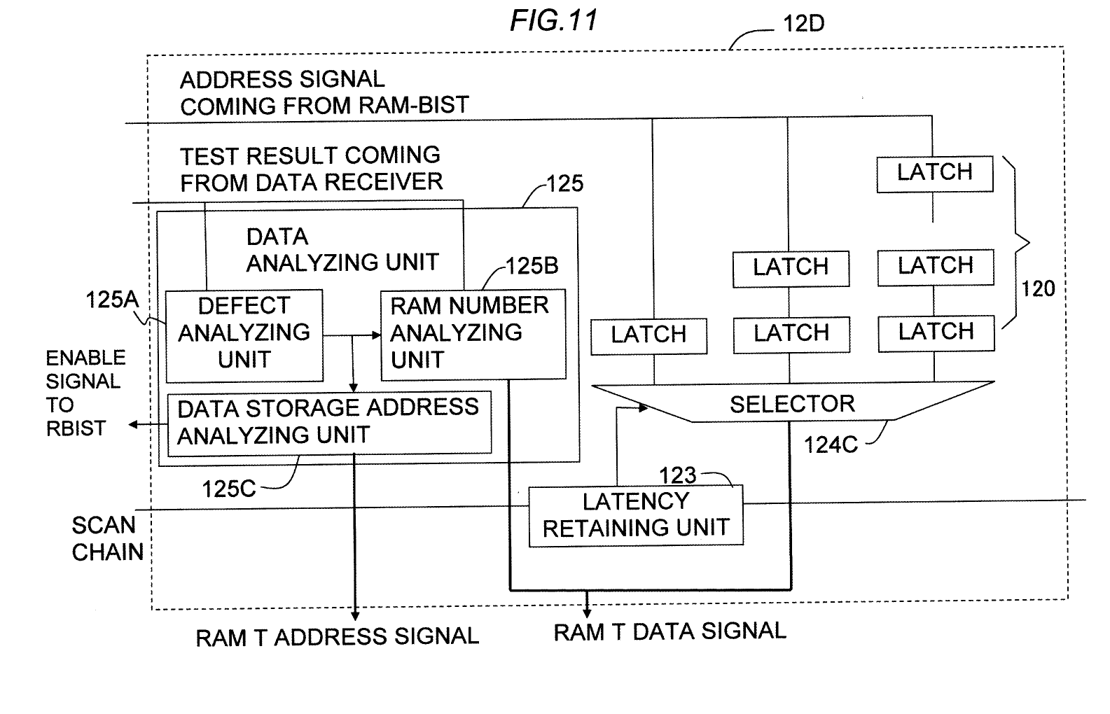

FIG. 11 depicts a configuration of the FBM control circuit 12D according to the Example 3. The FBM control circuit 12D includes, similarly to the Example 1 (FIG. 5) and the Example 2 (FIG. 8), a selector 124C for selecting the address signal and the latency retaining unit 123 to control the switchover of the selector 124C. On the other hand, a difference from the cases of the Examples 1 and 2 lies in a point that the FBM control circuit 12D includes a data analyzing unit 125. Furthermore, the data analyzing unit 125 includes a defect analyzing unit 125A, a RAM number analyzing unit 125B and a data storage address analyzing unit 125C.

As described above, each of the data receivers 15-1 through 15-N transmits the error existence/non-existence information about the test result for 1 word associated with the test address to the FBM control circuit 12D. The error existence/non-existence information transmitted from each of the data receivers 15-1 through 15-N is inputted to the defect analyzing unit 125A.

The defect analyzing unit 125A determines whether the error occurs or not and the number of the RAMs with occurrence of the error on the basis of the error existence/non-existence information.

Then, if it is reported that the error occurs in one or more of the data receivers 15-1 through 15-N, the defect analyzing unit 125A changes a status of an Enable signal to a Disable status in order to stop the signal coming from the RAM-BIST 11 during the write of the data to the RAM T, and transmits the Disable signal to the RAM-BIST 11. The RAM number analyzing unit 125B is notified of a result “error existence”.

The RAM number analyzing unit 125B determines, if the error exists, the RAM number of the RAM with the occurrence of the error, and outputs the RAM number and the test result contained in the data signal to the RAM T. A concrete process of the RAM number analyzing unit 125B will be exemplified as below.

Similarly to the defect analyzing unit 125A, the RAM number analyzing unit 125B also receives the error existence/non-existence information transmitted from the data receivers 15-1 through 15-N. The RAM number analyzing unit 125B generates the RAM numbers on the basis of pieces of information for identifying the sender data receivers 15-1 through 15-N, e.g., identification numbers, addresses, etc. of the sender data receivers 15-1 through 15-N. Further, the RAM number analyzing unit 125B requests the data receiver having reported the error through the error existence/non-existence information to send test result data (test results before being aggregated into 1-bit error existence/non-existence information) with respect to the test addresses, thus acquiring the test results. It may be sufficient that the data receiver requested to send the test result data sends the test results for 1 word in parallel. However, the data receiver may send the test results for 1 word serially because of stopping the write data given from the RAM-BIST 11 and stopping the tests of the RAM 1 through RAM N. Then, the RAM number analyzing unit 125B outputs the generated RAM numbers and the test results received from the data receivers 15-1 through 15-N to the RAM T.

On the other hand, in accordance with the latencies retained in the latency retaining unit 123, the selector 124C selects the address shifted back in time just as much as the quantity of latency from within the addresses given from the RAM-BIST 11, and outputs the selected address to the RAM T. Note that there is provided, though not illustrated in FIG. 11, a buffer to synthesize together the address signal of the error-occurrence address from the selector 124C and the RAM number and the test result data from the RAM number analyzing unit 125B, and, as in FIG. 10, synthesized data of the buffer may be stored in the RAM T.

The data storage address analyzing unit 125C indicates, if the error exists, a data storage address in the RAM T for storing the test result. For example, the data storage address analyzing unit 125C, if the error exists, counts up the address by “1” and indicates the storage destination address within the RAM T by sending the address signal to the RAM T.

The analyzing unit 125 executing the processes described above may be a hardware circuit configured by combining logic gates. The processes of the analyzing unit 125 are, however, the communication process with the data receivers 15-1 through 15-N and the analyzing process after setting the RAM-BIST 11 in the Disable status, and may not therefore operate in a way that works with the RAM-BIST 11. Accordingly, e.g., the data storage address analyzing unit 125C may be configured to include a central processing unit (CPU) or a digital signal processor (DSP) and a computer program on an unillustrated storage device.

Also in the FBM control circuit 12D described in the Example 3, the latency retaining unit 123 retains values containing the latencies of the RAM 1 through RAM N and the latencies of the data receivers 15-1 through 15-N with respect to the address signals that are output to the RAM 1 through RAM N from the RAM-BIST 11. Then, the input signal terminal of the selector 124 is selected corresponding to the values retained in the latency retaining unit 123, and the RAM T gets stored with the address given from the RAM-BIST 11 at the time adjusted as much as the time delay corresponding to the latency and with the test result data. Further, in the Example 3, the plurality of RAM 1 through RAM N is tested, and hence the RAM numbers based on the data receivers 15-1 through 15-N are allocated to the test result data. Accordingly, analyses of the test results are facilitated even in the case of testing the plurality of RAMs.

Moreover, in the semiconductor integrated circuit 10D according to the Example 3, the test results for 1 word per test address are temporarily aggregated into the 1-bit error existence/non-existence information, and the FBM control circuit 12D is notified of the error existence/non-existence information. Then, when the defect analyzing unit 125A detects the error, the data receiver notified of the error transmits the test results for 1 word to the RAM number analyzing unit 125B. In the meantime, RAM-BIST 11 stops transmitting the test address, thereby interrupting the test. However, such a possibility is low that the errors occur at the same clock cycle in the plural RAMs among the RAM 1 through RAM N. Therefore, also with the configurations in FIGS. 9 and 11, after restraining a substantial test speed from decreasing, the plurality of RAMs can be tested in parallel.

Still further, in the semiconductor integrated circuit 10D according to the Example 3, the test result data are stored in the RAM T when the error occur. Such processing enables the test time to be reduced to a great degree and the data analyzing time to be also reduced.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor integrated circuit comprising:
a test target memory;
a test result storage memory;
a test data generating unit to sequentially generate a test address signal and test data to be supplied to the test target memory; and
a control circuit including a delay circuit to delay, when sequentially storing in the test result storage memory test result data based on the test address signal and the test data supplied to the test target memory, a storage destination address signal to be supplied to the test result storage memory than the test address signal to be supplied to the test target memory, in accordance with a time delay containing at least a latency between supplying the test address signal to the test target memory and reading corresponding test result data.

2. The semiconductor integrated circuit according to claim 1, comprising a RAM to be used as both the test target memory and the test result storage memory,
wherein the control circuit includes:
a write data selecting unit to select as write data to the RAM, any one of the test result data based on read data read from the test target memory and the test data generated by the test data generating unit; and
an address selecting unit to select as a write address signal to the RAM, the test address signal generated by the test data generating unit and the storage destination address signal delayed from the test address signal by the delay circuit.

3. The semiconductor integrated circuit according to claim 2, wherein the RAM includes a test target area serving as the test target memory and a test result storage area serving as the test result storage memory,
the write data selecting unit selects the test data generated by the test data generating unit as the write data to the test target area, and selects the test result data as the write data to the test result storage area, and
the address selecting unit selects the test address signal as the write address signal to the test target area, and selects the storage destination address signal as the write address signal to the test result storage area.

4. The semiconductor integrated circuit according to claim 1, comprising a plurality of RAMs each serving as the test target memory,
wherein the control circuit outputs to the test result storage memory, among the test result data based on the read data read from the RAMs, test result data having been detected as including an error together with pieces of information for specifying a RAM and a test address of the detected error.

5. The semiconductor integrated circuit according to claim 1, further comprising a test result generating unit to generate the test result data by comparing the read data read from the test target memory with a predetermined expected value and to send the generated test result data to the test result storage memory via the control circuit.

6. A method of testing a semiconductor integrated circuit, comprising:
sequentially generating a test address signal and test data to be supplied to a test target memory; and
delaying, when sequentially storing test result data based on the test address signal and the test data supplied to the test target memory in the test result storage memory, a storage destination address signal to be supplied to the test result storage memory than the test address signal to be supplied to the test target memory, in accordance with a time delay containing at least a latency between supplying the test address signal to the test target memory and reading corresponding test result data.

7. The method of testing the semiconductor integrated circuit according to claim 6, wherein the semiconductor integrated circuit includes a RAM to be used as both the test target memory and the test result storage memory, the method further comprising:
selecting as write data to the RAM, any one of the test result data based on read data read from the test target memory and the generated test data; and
selecting as a write address signal to the RAM, the generated test address signal and the storage destination address signal delayed from the test address signal by the delaying.

8. The method of testing the semiconductor integrated circuit according to claim 7, the RAM including a test target area serving as the test target memory and a test result storage area serving as the test result storage memory,
wherein the generated test data is selected as the write data to the test target area and the test result data is selected as the write data to the test result storage area in the selecting of any one of the test result data and the test data, and
the test address signal is selected as the write address signal to the test target area and the storage destination address signal is selected as the write address signal to the test result storage area in the selecting of the test address signal and the storage destination address signal.

9. The method of testing the semiconductor integrated circuit according to claim 6, wherein the semiconductor integrated circuit includes a plurality of RAMs each serving as the test target memory, the method further comprising
outputting to the test result storage memory, among the test result data based on the read data read from the RAMs, test result data having been detected as including an error together with pieces of information for specifying a RAM and a test address of the detected error.

10. The method of testing the semiconductor integrated circuit according to claim 6, further comprising:
generating test result data by comparing the read data read from the test target memory with a predetermined expected value; and
sending the generated test result data to the test result storage memory via the control circuit.
